(19) United States
(12) Patent Application Publication
(10) Pub. No.: US 2025/0140303 A1
(43) Pub. Date: May 1, 2025

(54) SEMICONDUCTOR DEVICE PERFORMING REPLICA ROUTING

(71) Applicant: MICRON TECHNOLOGY, INC., BOISE, ID (US)

(72) Inventors: Honoka Enomoto, Tokyo (JP); Takashi Tomatsu, Akita-shi (JP); Masaru Morohashi, Tokyo (JP); Hideo Shimizu, Kanagawa (JP)

(73) Assignee: MICRON TECHNOLOGY, INC., Boise, ID (US)

(21) Appl. No.: 18/751,894

(22) Filed: Jun. 24, 2024

Related U.S. Application Data
(60) Provisional application No. 63/593,013, filed on Oct. 25, 2023.

(51) Int. Cl. G11C 11/4076; G11C 11/4096

(52) U.S. Cl. CPC G11C 11/4076; G11C 11/4096

(57) ABSTRACT

An example apparatus includes a first circuit configured to activate a first control signal, a second circuit configured to activate a first timing signal after receiving the first control signal, a third circuit configured to receive the first timing signal from the second control circuit and return back the first timing signal to the second control circuit, a first signal line conveying the first control signal from the first circuit to the second circuit, a second signal line conveying the first timing signal from the second circuit to the third circuit, and a third signal line conveying the first timing signal from the third circuit to the second circuit. Each of the first to third signal lines is provided on first and second tracks extending in parallel with each other.

### CROSS REFERENCE TO RELATED APPLICATION(S)

This application claims priority to U.S. Provisional Application No. 63/593,013, filed Oct. 25, 2023. The aforementioned application is incorporated herein by reference, in its entirety, for any purpose.

### BACKGROUND

In semiconductor memory devices such as a DRAM, the timing at which a read data reaches a control circuit may be different depending on the position of a memory cell array. In order to reduce this timing difference, the control circuit may include a timing adjustment circuit for adjusting the timing of transferring the read data output from the memory cell array to a data bus.

### BRIEF DESCRIPTION OF THE DRAWINGS

FIGS. 1A and 1B are schematic plan views for explaining a configuration of a semiconductor memory device according to an embodiment of the present disclosure;

FIG. 2 is a schematic circuit diagram for explaining functions of bank logic circuits;

FIG. 3 is a timing chart for explaining operations of the bank logic circuits; and

FIG. 4 is a schematic diagram for explaining a wiring pattern of command paths and replica paths.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

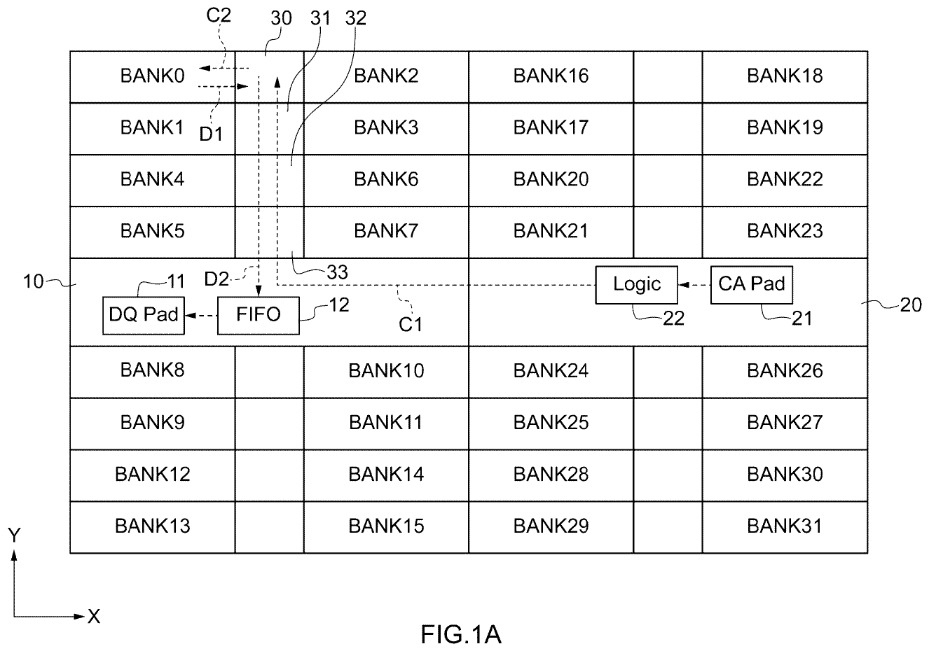

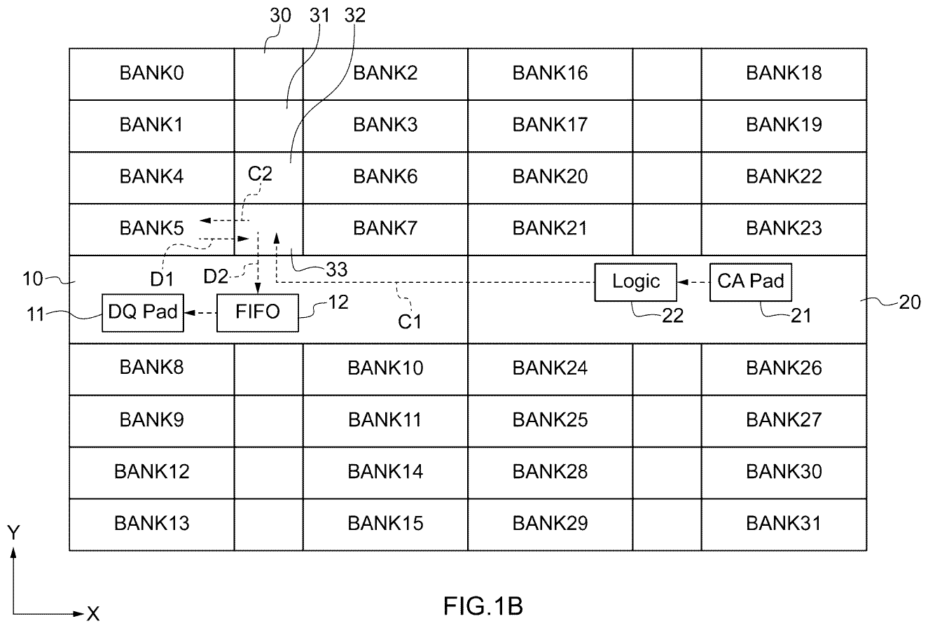

FIGS. 1A and 1B are schematic plan views for explaining a configuration of a semiconductor memory device according to an embodiment of the present disclosure. The semiconductor memory device according to the present embodiment is a DRAM and includes a plurality of memory banks BANK0 to BANK31 as shown in FIGS. 1A and 1B. A center area 10 is provided between the memory banks BANK0 to BANK7 and the memory banks BANK8 to BANK15, in which a data I/O terminal 11 and a data FIFO circuit 12, for example, are arranged. A center area 20 is provided between the memory banks BANK16 to BANK23 and the memory banks BANK24 to BANK31, in which a command address terminal 21 and a control logic circuit 22, for example, are arranged. When a read operation is to be performed, a read command and an address indicating a memory cell to be accessed are input to the command address terminal 21 from an external controller. The read command and the address are decoded by the control logic circuit 22, so that various internal control signals and internal addresses are generated.

FIG. 1A shows an example of accessing the memory bank BANK0. When access is to be made to the memory bank BANK0, the internal control signals and the internal addresses generated by the control logic circuit 22 are transferred to a bank logic circuit 30 via a command path C1. The bank logic circuit 30 is sandwiched between the memory bank BANK0 and the memory bank BANK2 in the X direction. The bank logic circuit 30 makes read access to the memory bank BANK0 via a command path C2 based on the internal control signals and the internal addresses transferred from the control logic circuit 22. When the memory bank BANK0 performs a read operation, a read data is read out in parallel from a plurality of memory cells included in the memory bank BANK0 via a data bus D1 and output to the bank logic circuit 30. The bank logic circuit 30 transfers the read data to the data FIFO circuit 12 via a data bus D2. The data FIFO circuit 12 converts the parallel read data to a serial data and outputs the converted data to the data I/O terminal 11. The bank logic circuit 30 may be assigned to the memory banks BANK0 and BANK2 in common. In this case, the operation identical to the above-described operation is performed also when access is to be made to the memory bank BANK2.

FIG. 1B shows an example of making access to the memory bank BANK5. When access is to be made to the memory bank BANK5, the internal control signals and the internal addresses generated by the control logic circuit 22 are transferred to a bank logic circuit 33 via the command path C1. The bank logic circuit 33 is sandwiched between the memory bank BANK5 and the memory bank BANK7 in the X direction. The bank logic circuit 33 makes read access to the memory bank BANK5 via the command path C2 based on the internal control signals and the internal addresses transferred from the control logic circuit 22. When the memory bank BANK5 performs a read operation, a read data is read out in parallel from a plurality of memory cells included in the memory bank BANK5 via the data bus D1 and output to the bank logic circuit 33. The bank logic circuit 33 transfers the read data to the data FIFO circuit 12 via the data bus D2. The data FIFO circuit 12 converts the parallel read data to a serial data and outputs the converted data to the data I/O terminal 11. The bank logic circuit 33 may be assigned to the memory banks BANK5 and BANK7 in common. In this case, the operation identical to the above-described operation is performed also when access is to be made to the memory bank BANK7.

A bank logic circuit 31 is provided between the memory bank BANK1 and the memory bank BANK3. The bank logic circuit 31 may be assigned to the memory banks BANK1 and BANK3 in common. In this case, the bank logic circuit 31 makes access to and transfers a data from the memory banks BANK1 and BANK3. A bank logic circuit 32 is provided between the memory bank BANK4 and the memory bank BANK6. The bank logic circuit 32 may be assigned to the memory banks BANK4 and BANK6 in common. In this case, the bank logic circuit 32 makes access to and transfers a data from the memory banks BANK4 and BANK6. However, the feature that two memory banks adjacent to each other in the X direction share one bank logic circuit is not essential. A bank logic circuit may be assigned to each memory bank.

The bank logic circuits 30 to 33 are arranged in the Y direction. In some examples, the X direction and the Y direction are perpendicular to one another. When viewed from the center area 10, the bank logic circuit 30 is the farthest, and the bank logic circuit 33 is the nearest. Therefore, the time from input of the read command and the address to the command address terminal 21 to start of the read operation by the memory bank BANK0 is longer than the time from input of the read command and the address to the command address terminal 21 to start of the read operation by the memory bank BANK5. As a result, the timing at which the read data is output from the memory bank BANK0 after the read command and the address are input to the command address terminal 21 is later than the timing at which the read data is output from the memory bank BANK5 after the read command and the address are input to the command address terminal 21. This is because the length of the command path C1 assigned to the memory bank BANK0 is longer than the length of the command path C1 assigned to the memory bank BANK5.

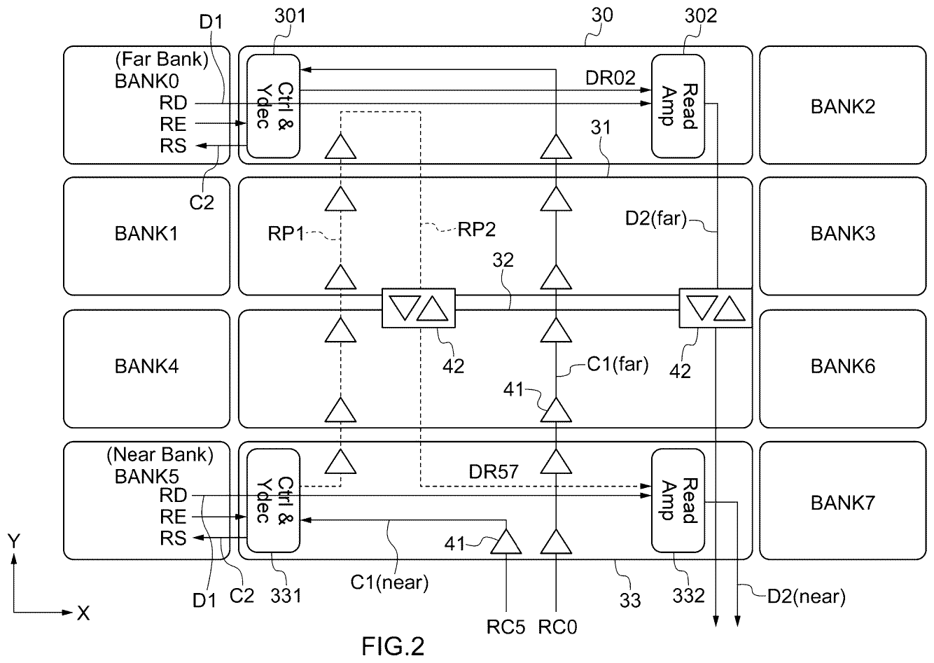

FIG. 2 is a schematic circuit diagram for explaining functions of the bank logic circuits 30 to 33. As shown in FIG. 2, the command path C1 is assigned to each of the memory banks BANK0 to BANK7. For example, the command path C1 assigned to the memory bank BANK0 supplies a control signal RC0 supplied from the control logic circuit 22 to a control circuit 301 included in the bank logic circuit 30. The control circuit 301 also includes a column decoder. When the control signal RC0 is input to the control circuit 301, the control circuit 301 supplies a read start signal RS to the memory bank BANK0 via the command path C2. When the read start signal RS is activated, the memory bank BANK0 starts a column selection operation to output a read data RD from a memory cell selected by a column address to the data bus D1, and also activates a read end signal RE. The read data RD is supplied to a read amplifier 302 included in the bank logic circuit 30. The read end signal RE is supplied to the control circuit 301. The control circuit 301 generates a data release signal DR02 in response to the read end signal RE and supplies the data release signal DR02 to the read amplifier 302. The read amplifier 302 outputs the read data RD to the data bus D2 in synchronization with the data release signal DR02.

Since the bank logic circuit 30 assigned to the memory bank BANK0 is arranged at the farthest position from the center area 10 in the Y direction, the command path C1 and the data bus D2 assigned to the bank logic circuit 30 are wired to cross the other bank logic circuits 31 to 33. The command path C1 assigned to the bank logic circuit 30 has a long wiring length in the Y direction with a plurality of buffer circuits 41 interposed therein. Therefore, before the control signal RC0 reaches the control circuit 301, a delay is caused by the wiring length of the command path C1 and by operations of the buffer circuits 41. Similarly, the data bus D2 assigned to the bank logic circuit 30 has a long wiring length in the Y direction with a bidirectional buffer circuit 42 interposed therein. Therefore, before the read data RD output from the read amplifier 302 reaches the data FIFO circuit 12, a delay is caused by the wiring length of the data bus D2 and by an operation of the bidirectional buffer circuit 42.

The command path C1 assigned to the memory bank BANK5 supplies a control signal RC5 supplied from the control logic circuit 22 to a control circuit 331 included in the bank logic circuit 33. The control circuit 331 also includes a column decoder. An operation after the control signal RC5 is input to the control circuit 331 is the same as the operation after the control signal RC0 is input to the control circuit 301. That is, the read data RD read out from the memory bank BANK5 is supplied to a read amplifier 332, and the read end signal RE is supplied to the control circuit 331. The control circuit 331 generates a data release signal DR57 in response to the read end signal RE and supplies the data release signal DR57 to the read amplifier 332. The read amplifier 332 outputs the read data RD to the data bus D2 in synchronization with the data release signal DR57.

Since the bank logic circuit 33 assigned to the memory bank BANK5 is arranged at the position nearest the center area 10 in the Y direction, each of the command path C1 and the data bus D2 assigned to the bank logic circuit 33 has a shorter wiring length in the Y direction than each of the command paths C1 and the data buses D2 assigned to the other bank logic circuits 30 to 32. In addition, the number of the buffer circuits 41 included in the command path C1 assigned to the bank logic circuit 33 is smaller than the number of the buffer circuits 41 included in the command path C1 assigned to each of the bank logic circuits 30 to 32. Further, the bidirectional buffer circuit 42 is not provided in the data bus D2 assigned to the bank logic circuit 33 in the example shown in FIG. 2. Therefore, the time from activation of the control signal RC5 to the time at which the control signal RC5 reaches the control circuit 331 is shorter than the time from activation of the control signal RC0 to the time at which the control signal RC0 reaches the control circuit 301. Similarly, the time until the read data RD output from the read amplifier 332 reaches the data FIFO circuit 12 is shorter than the time until the read data RD output from the read amplifier 302 reaches the data FIFO circuit 12.

In order to reduce the time differences described above, a path for supplying the data release signal DR57 to the read amplifier 332 is detoured in the present embodiment. A path denoted by reference signs RP1 in FIG. 2 is a replica of the command path C1 assigned to the bank logic circuit 30. The replica path RP1 has substantially the same wiring length as the command path C1 assigned to the bank logic circuit 30 and is also the same in the number of the buffer circuits 41 interposed. Further, a path denoted by reference sign RP2 in FIG. 2 is a replica of the data bus D2 assigned to the bank logic circuit 30. The replica path RP2 has substantially the same wiring length as the data bus D2 assigned to the bank logic circuit 30 and is also the same in the number of the bidirectional buffer circuits 42 interposed. This configuration reduces the time difference between the time from activation of the control signal RC0 to the time at which the read data RD read out from the memory bank BANK0 reaches the data FIFO circuit 12 and the time from activation of the control signal RC5 to the time at which the read data RD read out from the memory bank BANK5 reaches the data FIFO circuit 12.

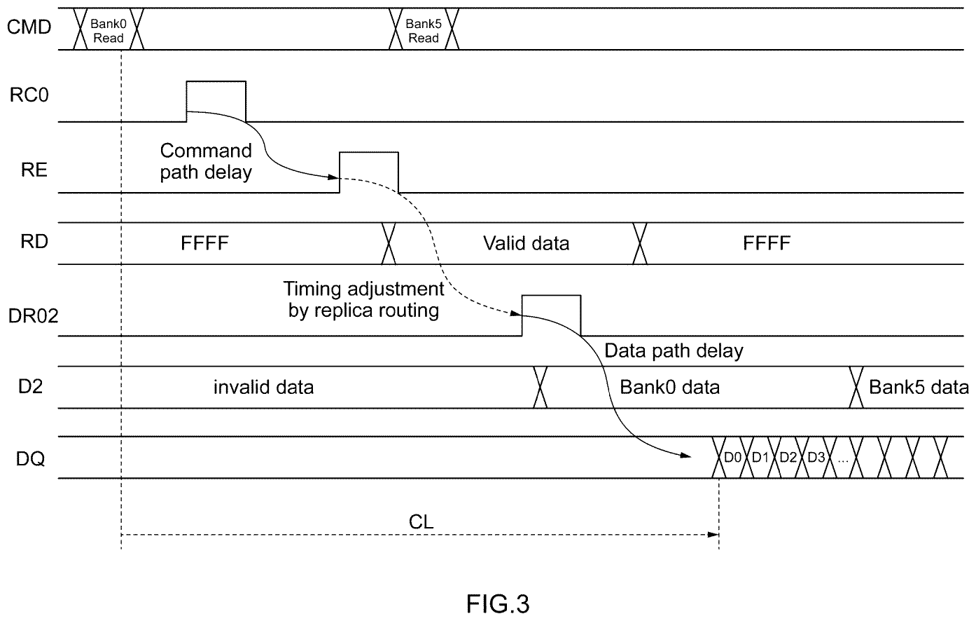

FIG. 3 is a timing chart for explaining operations of the bank logic circuits 30 to 33. FIG. 3 shows operations when a read command specifying the memory bank BANK0 is issued. First, when the read command specifying the memory bank BANK0 is issued, the control signal RC0 is generated by the control logic circuit 22 shown in FIG. 1A. As described above, when the control signal RC0 is input to the bank logic circuit 30, a read operation is performed by the memory bank BANK0. The read data RD is then output from the memory bank BANK0, and the read end signal RE is activated. Here, the time from activation of the control signal RC0 to activation of the read end signal RE is an eigenvalue that depends on the wiring length of the command path C1. After the read end signal RE is activated, the data release signal DR02 is activated at a predetermined timing. In response to activation of the data release signal DR02, the read amplifier 302 is activated, so that the read data RD is transferred to the data bus D2. The parallel read data RD on the data bus D2 is subjected to parallel/serial conversion by the data FIFO circuit 12 and, after a predetermined latency CL passes after issuance of the read command, is output from the data I/O terminal 11 in a burst manner. Here, the time from activation of the data release signal DR02 to start of the burst output of the read data RD is an eigenvalue that depends on the wiring length of the data bus D2. These eigenvalues are determined by the position of a memory bank in the Y direction. In the present embodiment, in order to reduce the timing difference caused by the difference between these eigenvalues, the time from activation of the read end signal RE to activation of the data release signal DR57 is made longer than the time from activation of the read end signal RE to activation of the data release signal DR02. This time adjustment is performed by using the replica paths RP1 and RP2 as described with reference to FIG. 2.

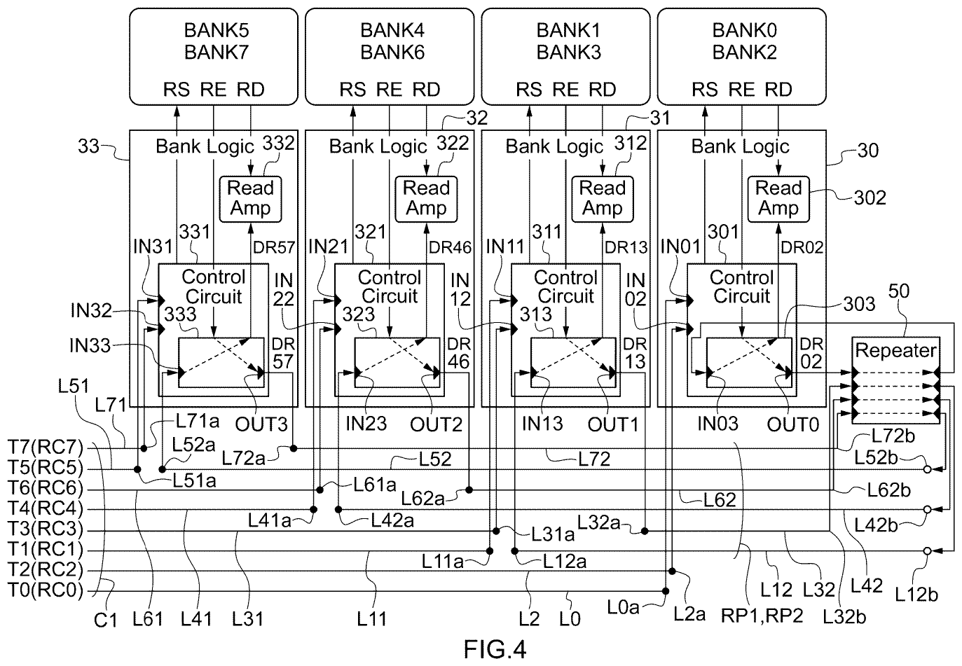

FIG. 4 is a schematic diagram for explaining a wiring pattern of the command paths C1 and the replica paths RP1 and RP2 for transmitting data release signals DR02, DR13, DR46, and DR57. As shown in FIG. 4, eight tracks T0 to T7 are used for the command paths C1 assigned to the memory banks BANK0 to BANK7 and the replica paths RP1 and RP2. All the tracks T0 to T7 extend in the Y-direction.

The tracks TO and T2 are assigned to the bank logic circuit 30 located at the far end. On the track TO, a signal line L0 is arranged which transmits the control signal RC0. On the track T2, a signal line L2 is arranged which transmits the control signal RC2. An end L0a of the signal line L0 and an end L2a of the signal line L2 are coupled to input nodes IN01 and IN02 of the control circuit 301 included in the bank logic circuit 30, respectively. The control circuit 301 supplies the read start signal RS to the memory bank BANK0 when the control signal RC0 is activated, and supplies the read start signal RS to the memory bank BANK2 when the control signal RC2 is activated. The control circuit 301 includes a driver circuit 303. When the read end signal RE is supplied from the memory bank BANK0 or BANK2, the driver circuit 303 transfers the data release signal DR02 from an output node OUT0 to a repeater circuit 50. The data release signal DR02 transferred to the repeater circuit 50 is returned to an input node IN03 of the driver circuit 303. That is, the output node OUT0 and the input node IN03 are short-circuited to each other via the repeater circuit 50. The driver circuit 303 supplies the data release signal DR02 returned to the input node IN03 to the read amplifier 302. Accordingly, the read data RD read out from the memory bank BANK0 or BANK2 is transferred to the data bus D2. As described above, when access is made to the memory bank BANK0 or BANK2, the data release signal DR02 does not pass through the replica paths RP1 and RP2, and therefore the delay amount of the data release signal DR02 is minimized.

The tracks T1 and T3 are assigned to the bank logic circuit 31 closer to the center area 10 than the bank logic circuit 30. On the track T1, a signal line L11 and a signal line L12 are arranged which respectively transmit a control signal RC1 and the data release signal DR13. On the track T3, a signal line L31 and a signal line L32 are arranged which respectively transmit a control signal RC3 and the data release signal DR13. An end L11a of the signal line L11 and an end L31a of the signal line L31 are coupled to input nodes IN11 and IN12 of the control circuit 311 included in the bank logic circuit 31, respectively. The control circuit 311 supplies the read start signal RS to the memory bank BANK1 when the control signal RC1 is activated, and supplies the read start signal RS to the memory bank BANK3 when the control signal RC3 is activated. The control circuit 311 includes a driver circuit 313. When the read end signal RE is supplied from the memory bank BANK1 or BANK3, the driver circuit 313 generates the data release signal DR13. The data release signal DR13 output from an output node OUT1 of the driver circuit 313 is supplied to one end L32a of the signal line L32 arranged on the track T3. The other end L32b of the signal line L32 is coupled to the repeater circuit 50. The data release signal DR13 supplied to the repeater circuit 50 is supplied to one end L12b of the signal line L12 arranged on the track T1. That is, the repeater circuit 50 short-circuits the end L32b of the signal line L32 and the end L12b of the signal line L12 to each other. The other end L12b of the signal line L12 is coupled to an input node IN13 of the driver circuit 313.

Accordingly, the data release signal DR13 output from the driver circuit 313 is supplied to the repeater circuit 50 via the signal line L32 and is then returned to the driver circuit 313 via the signal line L12. That is, the signal line L32 configures the replica path RP1, and the signal line L12 configures the replica path RP2. The driver circuit 313 supplies the data release signal DR13 returned to the input node IN13 to a read amplifier 312. Consequently, the read data RD read out from the memory bank BANK1 or BANK3 is transferred to the data bus D2. As described above, when access is made to the memory bank BANK1 or BANK3, the data release signal DR13 passes through the replica paths RP1 and RP2, and therefore the delay depending on the lengths of the replica paths RP1 and RP2 is given to the data release signal DR13. Since each of the wiring lengths of the signal lines L11 and L31 is shorter than each of the wiring lengths of the signal lines L0 and L2, the time from activation of the control signal RC1 or the control signal RC3 to generation of the data release signal DR13 is shorter than the time from activation of the control signal RC0 or the control signal RC2 to generation of the data release signal DR02. However, since the data release signal DR13 passes through the replica paths RP1 and RP2 arranged on the tracks T3 and T1, the above timing difference is eliminated. In addition, since the replica paths RP1 and RP2 are arranged on remaining regions of the tracks T3 and T1, no additional track is necessary. Further, another signal line is not arranged on the track T1 located between the end L11a of the signal line L11 and the end L12a of the signal line L12. Similarly, another signal line is not arranged on the track T3 located between the end L31a of the signal line L31 and the end L32a of the signal line L32.

The tracks T4 and T6 are assigned to the bank logic circuit 32 closer to the center area 10 than the bank logic circuit 31. On the track T4, a signal line L41 and a signal line L42 are arranged which respectively transmit a control signal RC4 and the data release signal DR46. On the track T6, a signal line L61 and a signal line L62 are arranged which respectively transmit a control signal RC6 and the data release signal DR46. An end L41a of the signal line L41 and an end L61a of the signal line L61 are coupled to input nodes IN21 and IN22 of a control circuit 321 included in the bank logic circuit 32, respectively. The control circuit 321 supplies the read start signal RS to the memory bank BANK4 when the control signal RC4 is activated, and supplies the read start signal RS to the memory bank BANK6 when the control signal RC6 is activated. The control circuit 321 includes a driver circuit 323. When the read end signal RE is supplied from the memory bank BANK4 or BANK6, the driver circuit 323 generates the data release signal DR46. The data release signal DR46 output from an output node OUT2 of the driver circuit 323 is supplied to one end L62a of the signal line L62 arranged on the track T6. The other end L62b of the signal line L62 is coupled to the repeater circuit 50. The data release signal DR46 supplied to the repeater circuit 50 is supplied to one end L42b of the signal line L42 arranged on the track T4. That is, the repeater circuit 50 short-circuits the end L62b of the signal line L62 and the end L42b of the signal line L42 to each other. The other end L42b of the signal line LA2 is coupled to an input node IN23 of the driver circuit 323.

Accordingly, the data release signal DR46 output from the driver circuit 323 is supplied to the repeater circuit 50 via the signal line L62 and is then returned to the driver circuit 323 via the signal line LA2. That is, the signal line L62 configures the replica path RP1, and the signal line L42 configures the replica path RP2. The driver circuit 323 supplies the data release signal DR46 returned to the input node IN23 to a read amplifier 322. Consequently, the read data RD read out from the memory bank BANK4 or BANK6 is transferred to the data bus D2. As described above, when access is made to the memory bank BANK4 or BANK6, the data release signal DR46 passes through the replica paths RP1 and RP2, and therefore the delay depending on the lengths of the replica paths RP1 and RP2 is given to the data release signal DR46. Since each of the wiring lengths of the signal lines L41 and L61 is shorter than each of the wiring lengths of the signal lines L11 and L31, the time from activation of the control signal RC4 or the control signal RC6 to generation of the data release signal DR46 is shorter than the time from activation of the control signal RC1 or the control signal RC3 to generation of the data release signal DR13. However, since the signal lines L62 and L42 configuring the replica paths RP1 and RP2 in the bank logic circuit 32 are longer than the signal lines L32 and L12 configuring the replica paths RP1 and RP2 in the bank logic circuit 31, the above timing difference is eliminated. In addition, the replica paths RP1 and RP2 are arranged on remaining regions of the tracks T6 and T4, no additional track is necessary. Further, another signal line is not arranged on the track T4 located between the end L41a of the signal line L41 and the end L42a of the signal line LA2. Similarly, another signal line is not arranged on the track T6 located between the end L61a of the signal line L61 and the end L62a of the signal line L62.

The tracks T5 and T7 are assigned to the bank logic circuit 33 located at the near end. On the track T5, a signal line L51 and a signal line L52 are arranged which respectively transmit the control signal RC5 and the data release signal DR57. On the track T7, a signal line L71 and a signal line L72 are arranged which respectively transmit a control signal RC7 and the data release signal DR57. An end L51a of the signal line L51 and an end L71a of the signal line L71 are coupled to input nodes IN31 and IN32 of the control circuit 331 included in the bank logic circuit 33, respectively. The control circuit 331 supplies the read start signal RS to the memory bank BANK5 when the control signal RC5 is activated, and supplies the read start signal RS to the memory bank BANK7 when the control signal RC7 is activated. The control circuit 331 includes a driver circuit 333. When the read end signal RE is supplied from the memory bank BANK5 or BANK7, the driver circuit 333 generates the data release signal DR57. The data release signal DR57 output from an output node OUT3 of the driver circuit 333 is supplied to one end L72a of the signal line L72 arranged on the track T7. The other end L72b of the signal line L72 is coupled to the repeater circuit 50. The data release signal DR57 supplied to the repeater circuit 50 is supplied to one end L52b of the signal line L52 arranged on the track T5. That is, the repeater circuit 50 short-circuits the end L72b of the signal line L72 and the end L52b of the signal line L52 to each other. The other end L52b of the signal line L52 is coupled to an input node IN33 of the driver circuit 333.

Accordingly, the data release signal DR57 output from the driver circuit 333 is supplied to the repeater circuit 50 via the signal line L72 and is then returned to the driver circuit 333 via the signal line L52. That is, the signal line L72 configures the replica path RP1, and the signal line L52 configures the replica path RP2. The driver circuit 333 supplies the data release signal DR57 returned to the input node IN33 to the read amplifier 332. Consequently, the read data RD read out from the memory bank BANK5 or BANK7 is transferred to the data bus D2. As described above, when access is made to the memory bank BANK5 or BANK7, the data release signal DR57 passes through the replica paths RP1 and RP2, and therefore the delay depending on the lengths of the replica paths RP1 and RP2 is given to the data release signal DR57. Since each of the wiring lengths of the signal lines L51 and L71 is shorter than each of the wiring lengths of the signal lines L41 and L61, the time from activation of the control signal RC5 or the control signal RC7 to generation of the data release signal DR57 is shorter than the time from activation of the control signal RC4 or the control signal RC6 to generation of the data release signal DR46. However, since the signal lines L72 and L52 configuring the replica paths RP1 and RP2 in the bank logic circuit 33 are longer than the signal lines L62 and L42 configuring the replica paths RP1 and RP2 in the bank logic circuit 32, the above timing difference is eliminated. In addition, the replica paths RP1 and RP2 are arranged on remaining regions of the tracks T7 and T5, no additional track is necessary. Further, another signal line is not arranged on the track T5 located between the end L51a of the signal line L51 and the end L52a of the signal line L52. Similarly, another signal line is not arranged on the track T7 located between the end L71a of the signal line L71 and the end L72a of the signal line L72.

As described above, the semiconductor memory device according to the present embodiment causes the data release signals DR13, DR46, and DR57 to detour by using the replica paths RP1 and RP2. Therefore, the timing difference can be reduced with high accuracy. In addition, since the replica paths RP1 and RP2 are arranged on available areas of the tracks T0 to T7 assigned to signal lines for the control signals RC0 to RC7, no additional track is necessary.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
first and second tracks extending in parallel with each other,
a first circuit configured to activate a first control signal;
a second circuit configured to activate a first timing signal after receiving the first control signal;
a third circuit configured to receive the first timing signal from the second control circuit and return back the first timing signal to the second control circuit;
a first signal line conveying the first control signal from the first circuit to the second circuit;
a second signal line conveying the first timing signal from the second circuit to the third circuit; and
a third signal line conveying the first timing signal from the third circuit to the second circuit,
wherein the first signal line is provided on a first section of the first track,
wherein the second signal line is provided on one of a second section of the first track and a first section of the second track, and
wherein the third signal line is provided on the other of the second section of the first track and the first section of the second track.

2. The apparatus of claim 1, further comprising a first memory cell array,
wherein the first circuit is configured to activate the first control signal responsive to a first external command that instructs a read operation to the first memory cell array.

3. The apparatus of claim 2, wherein the first memory cell array is configured to start an output operation of a read data responsive to the first control signal.

4. The apparatus of claim 3, wherein the first timing signal is activated at substantially the same timing when the first memory cell array finishes outputting the read data to a fourth circuit.

5. The apparatus of claim 4, further comprising a data bus,
wherein the fourth circuit is configured to transfer the read data to the data bus responsive to the first timing signal passed through the third and second circuits.

6. The apparatus of claim 5, further comprising:
a fourth signal line provided on a second section of the second track; and
a second memory cell array,
wherein the first circuit is configured to activate a second control signal responsive to a second external command that instructs a read operation to the second memory cell array,
wherein the fourth signal line conveys the second control signal from the first circuit to the second circuit,
wherein the second memory cell array is configured to start an output operation of a read data responsive to the second control signal, and
wherein the first timing signal is activated at substantially the same timing when the second memory cell array finishes outputting the read data to the fourth circuit.

7. The apparatus of claim 6, wherein the read data output from the second memory cell array is transferred from the fourth circuit to the data bus responsive to the first timing signal passed through the third and second circuits.

8. The apparatus of claim 7, further comprising third and fourth memory cell arrays,
wherein the first circuit is configured to activate a third control signal responsive to a third external command that instructs a read operation to the third memory cell array, and
wherein the first circuit is configured to activate a fourth control signal responsive to a fourth external command that instructs a read operation to the fourth memory cell array.

9. The apparatus of claim 8, further comprising:
third and fourth tracks extending in parallel with each other,
a fifth circuit configured to activate a second timing signal after receiving either the third control signal or the fourth control signal;
a fifth signal line conveying the third control signal from the first circuit to the fourth circuit;
a sixth signal line conveying the fourth control signal from the first circuit to the fourth circuit;
a seventh signal line conveying the second timing signal from the fourth circuit to the third circuit; and
an eighth signal line conveying the second timing signal from the third circuit to the fourth circuit,
wherein the third circuit is configured to receive the second timing signal from the fifth circuit via the seventh signal line and return back the second timing signal to the fifth circuit via the eighth signal line,
wherein the third memory cell array is configured to start an output operation of a read data responsive to third control signal,
wherein the fourth memory cell array is configured to start an output operation of a read data responsive to the fourth control signal,
wherein the second timing signal is activated at substantially the same timing when either the third memory cell array or the fourth memory cell array finishes outputting the read data to a six circuit,
wherein the fifth signal line is provided on a first section of the third track,
wherein the sixth signal line is provided on a first section of the fourth track,
wherein the seventh signal line is provided on one of a second section of the third track and a second section of the fourth track, and
wherein the eighth signal line is provided on the other of the second section of the third track and the second section of the fourth track.

10. The apparatus of claim 9,
wherein each of the first and fourth signal lines is shorter than each of the fifth and sixth signal lines, and
wherein each of the second and third signal lines is longer than each of the seventh and eighth signal lines.

11. The apparatus of claim 10, wherein a sum of lengths of the first, second, third, and fourth signal lines is substantially a same as a sum of lengths of the fifth, sixth, seventh, and eighth signal lines.

12. An apparatus comprising:
first and second signal lines provided on a first track, the first signal line having a first end, the second signal line having second and third ends;
third and fourth signal lines provided on a second track, the third signal line having a fourth end, the fourth signal line having fifth and sixth ends; and
a first control circuit having a first input node coupled to the first end of the first signal line, a second input node coupled to the fourth end of the third signal line, a third input node coupled to the fifth end of the fourth signal line, and a first output node coupled to the second end of the second signal line,
wherein the first and second tracks extend in parallel with each other,
wherein the first control circuit is configured to output a first timing signal to the first output node responsive to either a first control signal supplied to the first input node or a second control signal supplied to the second input node, and
wherein the third end of the second signal line and the sixth end of the fourth signal line are short-circuited to each other.

13. The apparatus of claim 12, further comprising:
a first memory cell array; and
a data bus
wherein the first control circuit is configured to supply a first read signal to the first memory cell array responsive to either the first control signal or the second control signal,
wherein the first memory cell array is configured to start an output operation of a first read data responsive to the first read signal, and
wherein the first control circuit is configured to transfer the first read data to the data bus responsive to the first timing signal supplied to the third input node.

14. The apparatus of claim 12,
wherein the first track is free from any signal line between the first end of the first signal line and the second end of the second signal line, and
wherein the second track is free from any signal line between the fourth end of the third signal line and the fifth end of the fourth signal line.

15. The apparatus of claim 12, further comprising:
fifth and sixth signal lines provided on a third track, the fifth signal line having a seventh end, the sixth signal line having eighth and ninth ends;
seventh and eighth signal lines provided on a fourth track, the seventh signal line having a tenth end, the eighth signal line having eleventh and twelfth ends; and
a second control circuit having a fourth input node coupled to the seventh end of the fifth line, a fifth input node coupled to the tenth end of the seventh signal line, a sixth input node coupled to the eleventh end of the eighth signal line, and a second output node coupled to the eighth end of the sixth signal line,
wherein the first, second, third, and fourth tracks extend in parallel with one another,
wherein the second control circuit is configured to output a second timing signal to the second output node responsive to either a third control signal supplied to the fourth input node or a fourth control signal supplied to the fifth input node,
wherein the ninth end of the sixth signal line and the twelfth end of the eighth signal line are short-circuited to each other,
wherein each of the first and third signal lines is shorter than each of the fifth and seventh signal lines, and
wherein each of the second and fourth signal lines is longer than each of the sixth and eighth signal lines

16. The apparatus of claim 15, further comprising:
first and second memory cell arrays; and
a data bus,
wherein the first control circuit is configured to supply a first read signal to the first memory cell array responsive to either the first control signal or the second control signal,
wherein the second control circuit is configured to supply a second read signal to the second memory cell array responsive to either the third control signal or the fourth control signal,
wherein the first memory cell array is configured to start an output operation of a first read data responsive to the first read signal,
wherein the second memory cell array is configured to start an output operation of a second read data responsive to the second read signal,
wherein the first control circuit is configured to transfer the first read data to the data bus responsive to the first timing signal supplied to the third input node, and
wherein the second control circuit is configured to transfer the second read data to the data bus responsive to the second timing signal supplied to the sixth input node.

17. The apparatus of claim 15,
wherein the first track is free from any signal line between the first end of the first signal line and the second end of the second signal line, and
wherein the second track is free from any signal line between the fourth end of the third signal line and the fifth end of the fourth signal line,
wherein the third track is free from any signal line between the seventh end of the fifth signal line and the eighth end of the sixth signal line, and
wherein the fourth track is free from any signal line between the tenth end of the seventh signal line and the eleventh end of the eighth signal line.

18. An apparatus comprising:
first and second memory banks;
a repeater circuit;
a first control circuit provided correspondingly to the first and second memory banks, the first control circuit, in response to receiving either a first read control signal associated with the first memory bank or a second read control signal associated with the second memory bank, configured to:
generate a first read timing signal;
transfer the first read timing signal as a first forward timing signal to the repeater circuit;
receive the first forward timing signal as a first backward timing signal from the repeater circuit; and
activate a first read amplifier responsive to the first backward timing signal;
wherein one of the first read control signal and the second read control signal is transferred on the same track as one of the first forward timing signal and the first backward timing signal.

19. The apparatus of claim 18, wherein the other of the first read control signal and the second read control signal is transferred on the same track as the other of the first forward timing signal and the first backward timing signal.

20. The apparatus of claim 18, further comprising:
third and fourth memory banks;
a second control circuit provided correspondingly to the third and fourth memory banks, the second control circuit, in response to receiving either a third read control signal associated with the third memory bank or a fourth read control signal associated with the fourth memory bank, configured to:
generate a second read timing signal;
transfer the second read timing signal as a second forward timing signal to the repeater circuit;
receive the second forward timing signal as a second backward timing signal from the repeater circuit; and
activate a second read amplifier responsive to the second backward timing signal;
wherein one of the third read control signal and the fourth read control signal is transferred on the same track as one of the second forward timing signal and the second backward timing signal.

21. The apparatus of claim 20, wherein the other of the third read control signal and the fourth read control signal is transferred on the same track as the other of the second forward timing signal and the second backward timing signal.
